(19) United States
(12) Patent Application Publication
(10) Pub. No.: US 2020/0381612 A1
(43) Pub. Date: Dec. 3, 2020

(54) NON-CONTACT FORCE TYPE MICRO-ROTATING MECHANISM AND PREPARATION METHOD THEREOF

(71) Applicants: Research & Development Institute of Northwestern Polytechnical University In Shenzhen, Shenzhen (CN); Northwestern Polytechnical University, Xi'an (CN)

(72) Inventors: Yiting YU, Shenzhen (CN); Dongqin CHEN, Shenzhen (CN); Mengfei XU, Shenzhen (CN); Kai AN, Shenzhen (CN); Kui ZHOU, Shenzhen (CN)

(73) Assignees: Research & Development Institute of Northwestern Polytechnical University In Shenzhen, Shenzhen, Guangdong (CN); Northwestern Polytechnical University, Xi'an (CN)

(21) Appl. No.: 16/879,095

(22) Filed: May 20, 2020

(30) Foreign Application Priority Data
May 29, 2019 (CN) 201910454194.5

(51) Int. Cl. H01L 41/187; H02N 2/10; H01L 41/20

(52) U.S. Cl. CPC H01L 41/187; H01L 41/20; H02N 2/10

(57) ABSTRACT

A non-contact force type micro-rotating mechanism driven by attractive/repulsive force and a manufacturing method thereof, belongs to the field of intelligent micro devices, and mainly relates to micro electromechanical system technology, precision machining technology, precision assembly and the like. The mechanism adopts the interaction force between magnetic poles to replace the connection mode of a traditional through-hole bearing pressure spring positioning shaft, so that the component part structure of the mechanism can be optimized, and the space utilization rate can be greatly improved. Moreover, the attractive force type structure also has the effect of weakening the radial vibration of the motor, and the coaxiality of the rotor and the stator is improved in the running process of the motor. Meanwhile, the rotating mechanism does not directly output shaft work, a structure can be added on the disc-shaped rotor to realize different functions, an actuator and a control object are integrated.

### CROSS-REFERENCE TO RELATED APPLICATION

This application claims priority to Chinese Application No. 201910454194.5 filed on May 29, 2019, the entire contents of which are herein incorporated by reference.

### TECHNICAL FIELD

The disclosure belongs to the field of intelligent micro devices, and mainly relates to micro electromechanical system technology, precision machining technology, precision assembly and the like.

### BACKGROUND

Ultrasonic motor is a brand-new concept micro-motor developed at the end of the 20th century. Different from the principle of the traditional electromagnetic motor, the inverse piezoelectric effect of piezoelectric material is utilized so that an elastic body stator vibrates in an ultrasonic frequency band, torque and motion are obtained through the frictional coupling between the rotor and the elastic body stator to drive the rotor. The ultrasonic motor has the advantages of small volume, light weight, compact structure, fast response, low noise, no electromagnetic interference and the like, so that the ultrasonic motor plays an important role in modern weapon equipment, industrial automation, home life automation and office automation. The ultrasonic motor is free of coil, simple in structure, easy to process, and wide in application scenarios in the fields of micro-electromechanical systems (MEMS) and the like, miniaturization and integration are important development directions of the ultrasonic motor.

A longitudinal/torque piezoelectric motor (Kurosawa M, Ueha S.IEEE Transactions on Ultrasonics, Ferroelectrics and Frequency Control, 1991, 38(2): 89-92) was developed by Kurosawa in 1991, a long shaft penetrate through central hole of the stator and the rotor, the rotor is pressed against the stator by virtue of spring deformation force, the pre-load pressure applied to the rotor is 90 N, the diameter of the motor is 50 mm, and the full length of the motor is about 82 mm. In 1999, researchers of Japanese Seiko Instrument Co., Ltd. developed a miniature rod-type ultrasonic motor (SuzukiY, TaniK, SakuharaT. Sensors and Actuators A: Physical, 2000, 83(3): 244-248.), the center part of a leaf spring and the top of the shaft are welded, and the contact pressure between the stator and the rotor is generated by bending a suspension component to the rotor through a flat spring structure. The novel motor is 2 mm in diameter and 0.3 mm in height. It can be seen that the manner in which the pre-pressure is applied has an important effect on the miniaturization and integration of the ultrasonic motor. According to an implementation method of a non-contact force type micro-rotating mechanism provided by the disclosure, the friction between the stator and the rotor is guaranteed through magnetic force, and the volume of the motor can be greatly reduced.

### SUMMARY

In order to improve the shortcomings of the traditional rotary driving device in the aspects of complex composition, low mechanical efficiency and the like, which causes by contact type pretightening force provided by using a pressure spring and the like, the disclosure provides an implementation method of a non-contact force type micro-rotating mechanism, which is simple and compact in structure, convenient to integrate, and is applicable to the fields of silicon wafers, integrated circuit chips and the like.

Referring to FIGS. 1A and 1B, the non-contact force type micro-rotating mechanism provided by the disclosure has two implementations: the attractive force type rotating mechanism (as shown in FIG. 1A) and the repulsive force type rotating mechanism (as shown in FIG. 1B).

The attractive force type rotating mechanism consists of wafer 1, the first magnet 2, elastic body 3, piezoelectric ceramic 4, the first base 5, the second magnet 6 and the first shell 7. The wafer 1 and the first magnet 2 form the rotor part. The wafer 1 and the first magnet 2 are bonded coaxially. A layer of wear-resistant material, such as polytetrafluoroethylene-based friction material, is added to the wafer 1 to improve the mechanical properties and prolong service life. The elastic body 3 and the piezoelectric ceramic 4 form the stator part. The elastic body 3 and the piezoelectric ceramic 4 are also bonded coaxially. The elastic body 3 is an annular structure, and mechanical vibration of the piezoelectric ceramic 4 is about to propagate in the elastic body 3 in the form of waves. A reinforcing rib on the inner ring of the elastic body 3 is used for increasing the strength and rigidity of the elastic body 3 and overcoming twisted deformation caused by uneven stress during working. On the one hand, the tooth-shaped structure on the elastic body 3 is used for amplifying the vibration amplitude of the stator under the condition that the bending rigidity of the stator ring is basically kept unchanged. On the other hand, debris generated by friction between the stator and the rotor can be accommodated in grooves of the tooth-shaped structure, so that the normal operation of the motor is guaranteed. The stator, the rotor and the second magnet 6 are coaxially assembled. The first magnet 2 of the rotor part is arranged in the elastic body 3 of the stator part. The first magnet 2 and the elastic body 3 are in clearance fit to ensure normal rotation. The attractive force type rotating mechanism utilizes mutual attraction of the first magnet 2 on the rotor and the second magnet 6 on the first base 5 with opposite magnetic poles to provide pre-pressure required for rotation.

The repulsive force type rotating mechanism consists of wafer 1, first magnet 2, elastic body 3, piezoelectric ceramic 4, the second magnet 6, the second base 8 and the first shell 9. The wafer 1 and the first magnet 2 form the rotor part. The wafer 1 and the first magnet 2 are bonded coaxially. A layer of wear-resistant material, such as polytetrafluoroethylene-based friction material, is added to the wafer 1 to improve the mechanical properties and prolong service life. The elastic body 3 and the piezoelectric ceramic 4 form the stator part. The elastic body 3 and the piezoelectric ceramic 4 are also bonded coaxially. The elastic body 3 is of an annular structure, and mechanical vibration of the piezoelectric ceramic 4 is about to propagate in the elastic body 3 in the form of waves. A reinforcing rib on the inner ring of the elastic body 3 is used for increasing the strength and rigidity of the elastic body 3 and overcoming twisted deformation caused by uneven stress during working. On the one hand, the tooth-shaped structure on the elastic body 3 is used for amplifying the vibration amplitude of the stator under the condition that the bending rigidity of the stator ring is basically kept unchanged. On the other hand, debris generated by friction between the stator and the rotor can be accommodated in grooves of the tooth-shaped structure, so that the normal operation of the motor is guaranteed. The stator, the rotor and the second magnet 6 are coaxially assembled. The first magnet 2 on the rotor and the stator are in clearance fit to ensure normal rotation. The repulsive force type rotating mechanism utilizes mutual repulsion of the first magnet 2 on the rotor and the second magnet 6 on the second shell 9 with same magnetic poles to provide pre-pressure required for rotation.

The working principle of the attractive force type rotating mechanism refers to FIG. 1A. Two alternating voltages of ultrasonic frequencies with the phase difference of 90 degrees are applied to the piezoelectric ceramic 4, and the piezoelectric ceramic 4 is periodically deformed due to the inverse piezoelectric effect of the piezoelectric material, so that mechanical vibration of ultrasonic frequency of dozens of kilohertz is generated. When the piezoelectric ceramic 4 is combined with the elastic body 3 together, the mechanical vibration propagates in the elastic body 3 in the form of waves, so that particles with a driving effect on the surface of the vibrating body form the ultrasonic frequency micro-vibration of an elliptical trajectory. The first magnet 2 compresses the elastic body 3 due to the attractive force of the second magnet 6, and the surface of the vibrating body pushes the rotor part in contact with the surface of the vibrating body to rotate by means of frictional force.

The working principle of the repulsive force type rotating mechanism refers to FIG. 1B. Two alternating voltages of ultrasonic frequencies with the phase difference of 90 degrees are applied to the piezoelectric ceramic 4, and the piezoelectric ceramic 4 is periodically deformed due to the inverse piezoelectric effect of the piezoelectric material, so that mechanical vibration of ultrasonic frequency of dozens of kilohertz is generated. When the piezoelectric ceramic 4 is combined with the elastic body 3 together, the mechanical vibration propagates in the elastic body 3 in the form of waves, so that particle with a driving effect on the surface of the vibrating body form the ultrasonic frequency micro-vibration of an elliptical trajectory. The first magnet 2 compresses the elastic body 3 due to the repulsive force of the second magnet 6, and the surface of the vibrating body pushes the rotor part in contact with the surface of the vibrating body to rotate by means of frictional force.

Referring to FIGS. 2A through 2I, the preparation method of the attractive force type micro-rotating mechanism provided by the disclosure, comprising the following basic processing steps: step one, referring to FIG. 2A, machining the wafer 1 by using the machine tool; step two, referring to FIG. 2B, bonding the wafer 1 and the magnet 2 by using a displacement table to obtain the rotor part of the motor; step three, referring to FIG. 2C, machining the tooth-shaped elastic body 3 by using the machine tool; step four, referring to FIG. 2D, bonding the elastic body 3 and the piezoelectric ceramic 4 by using the displacement table to obtain the stator part of the motor; step five, referring to FIG. 2E, milling the first base 5 on a substrate with certain thickness; step six, referring to FIG. 2F, embedding the second magnet 6 into the first base 5 to obtain the magnetic base; step seven, referring to FIG. 2G, milling the first base 7 on the substrate with certain thickness; and step eight, referring to FIGS. 2H and 2I, assembling the shell, the rotor, the stator and the magnetic base together from top to bottom to obtain the complete motor.

Referring to FIGS. 3A through 3I, the preparation method of a repulsive force type micro-rotating mechanism provided by the disclosure, comprising the following basic processing steps: step one, referring to FIG. 3A, machining the wafer 1 by using a machine tool; step two, referring to FIG. 3B, bonding the wafer 1 and the magnet 2 by using a displacement table to obtain the rotor part of the motor; step three, referring to FIG. 3C, machining the tooth-shaped elastic body 3 by using the machine tool; step four, referring to FIG. 3D, bonding the elastic body 3 and the piezoelectric ceramic 4 by using the displacement table to obtain the stator part of the motor; step five, referring to FIG. 3E, milling the second base 8 on the substrate with certain thickness; step six, referring to FIG. 3F, milling the second shell 9 on the substrate with certain thickness; step seven, referring to FIG. 3G, embedding the second magnet 6 into the second base 9 to obtain the magnetic shell; and step eight, referring to FIGS. 3H and 3I, assembling the magnetic shell, the rotor, the stator and the base together from top to bottom to obtain the complete motor.

The implementation method of the non-contact force type micro-rotating mechanism provided by the disclosure adopts the interaction force between magnetic poles to replace the connection mode of the traditional through-hole bearing pressure spring positioning shaft, so that the component part structure of the mechanism can be optimized, and the space utilization rate can be greatly improved. Moreover, the attractive force type structure also has the effect of weakening the radial vibration of the motor, and the coaxiality of the rotor. The stator is improved in the running process of the motor. When the magnet is selected, it should be noted that the magnitude of provided prestress is appropriate, the friction, wear and noise between the stator and the rotor are taken into account. And at the same time ensure that the motor has good output performance. The appropriate prestress can enable the motor to be high in no-load speed and large in output torque. Meanwhile, the rotating mechanism does not directly output shaft work, the structure can be added on the disc-shaped rotor to realize different functions, an actuator and the control object are integrated. For example, when the rotor is made of the glass material, the grating or the filter coating and the like can be added on the rotor to obtain polarized light or light with the specific wavelength, integration and chip design of the motor and the filter wheel can be realized, and the volume of related devices is greatly reduced. The disclosure provides a feasible idea for implementing chip application of the micro motor.

### BRIEF DESCRIPTION OF THE DRAWINGS

FIG. 1A depicts a non-contact force type micro-rotating mechanism;

FIG. 1B depicts a non-contact force type micro-rotating mechanism;

FIG. 2A depicts an attractive force type micro-rotating mechanism;

FIG. 2B depicts an attractive force type micro-rotating mechanism;

FIG. 2C depicts an attractive force type micro-rotating mechanism;

FIG. 2D depicts an attractive force type micro-rotating mechanism;

FIG. 2E depicts an attractive force type micro-rotating mechanism;

FIG. 2F depicts an attractive force type micro-rotating mechanism;

FIG. 2G depicts an attractive force type micro-rotating mechanism;

FIG. 2H depicts an attractive force type micro-rotating mechanism;

FIG. 2I depicts an attractive force type micro-rotating mechanism;

FIG. 3A depicts a repulsive force type micro-rotating mechanism;

FIG. 3B depicts a repulsive force type micro-rotating mechanism;

FIG. 3C depicts a repulsive force type micro-rotating mechanism;

FIG. 3D depicts a repulsive force type micro-rotating mechanism;

FIG. 3E depicts a repulsive force type micro-rotating mechanism;

FIG. 3F depicts a repulsive force type micro-rotating mechanism;

FIG. 3G depicts a repulsive force type micro-rotating mechanism;

FIG. 3H depicts a repulsive force type micro-rotating mechanism;

FIG. 3I depicts a repulsive force type micro-rotating mechanism; and

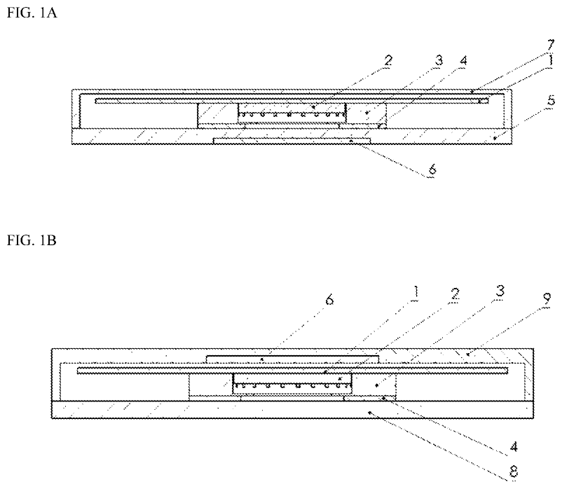

wherein, 1, wafer; 2, first magnet; 3, elastic body; 4, piezoelectric ceramic; 5, first base; 6, second magnet; 7, first shell; 8, second base; and 9, second shell.

### DETAILED DESCRIPTION

### Embodiment 1

The embodiment is an attractive force type rotating mechanism, which consists of the wafer 1 made of the glass material with the diameter phi of 25 mm and the thickness of 0.3 mm, the rubidium-iron-boron first magnet 2 with the diameter phi of 6.8 mm and the thickness of 0.6 mm, the toothed annular phosphor bronze elastic body 3 with the inner diameter phi of 6.9 mm and the outer diameter phi of 12 mm, the piezoelectric ceramic 4 with electrodes with the thickness of 0.3 mm, the inner diameter phi of 6.9 mm and the outer diameter phi of 12 mm, the first base 5 with the thickness of 1 mm with a blind hole with the diameter phi of 10 mm and the depth of 0.4 mm, the rubidium-iron-boron second magnet 6 with the diameter phi of 6.8 mm and the thickness of 0.6 mm, and the first shell 7 made of a PMMA material. The wafer 1 and the first magnet 2 form the rotor part, and the wafer 1 and the first magnet 2 are bonded coaxially. A layer of wear-resistant material, such as polytetrafluoroethylene-based friction material, may be added to the wafer 1 to improve mechanical properties and prolong service life. The elastic body 3 and the piezoelectric ceramic 4 form the stator part, and the elastic body 3 and the piezoelectric ceramic 4 are also bonded coaxially. The elastic body 3 is of an annular structure, and mechanical vibration of the piezoelectric ceramic 4 is about to propagate in the elastic body 3 in the form of waves. The reinforcing rib on the inner ring of the elastic body 3 is used for increasing the strength and rigidity of the elastic body 3 and overcoming twisted deformation caused by uneven stress during working. On one hand, the tooth-shaped structure on the elastic body 3 is used for amplifying the vibration amplitude of the stator under the condition that the bending rigidity of the stator ring is basically kept unchanged. And on the other hand, debris generated by friction between the stator and the rotor can be accommodated in grooves of the tooth-shaped structure, so that the normal operation of the motor is guaranteed. The stator, the rotor and the second magnet 6 are coaxially assembled, the first magnet 2 of the rotor part is arranged in the elastic body 3 of the stator part, and the first magnet 2 and the elastic body 3 are in clearance fit to ensure normal rotation. The attractive force type rotating mechanism utilizes mutual attraction of the first magnet 2 on the rotor and the second magnet 6 on the first base 5 with opposite magnetic poles to provide pre-pressure required for rotation.

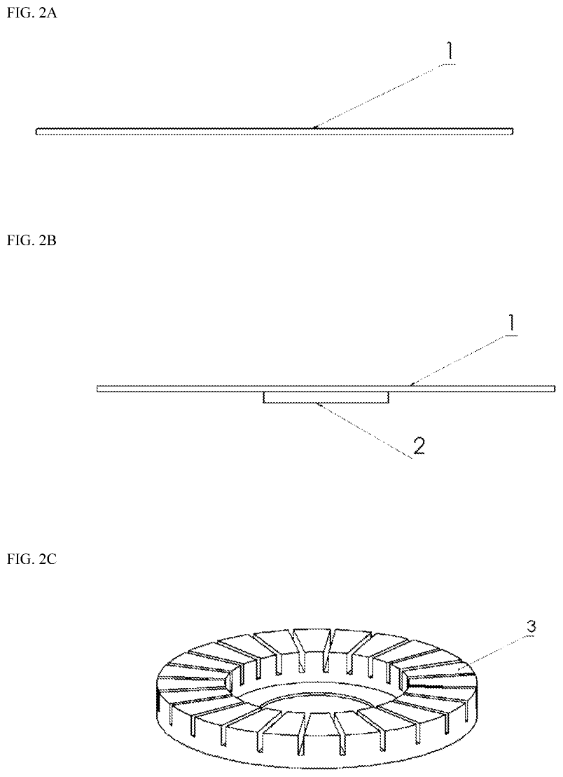

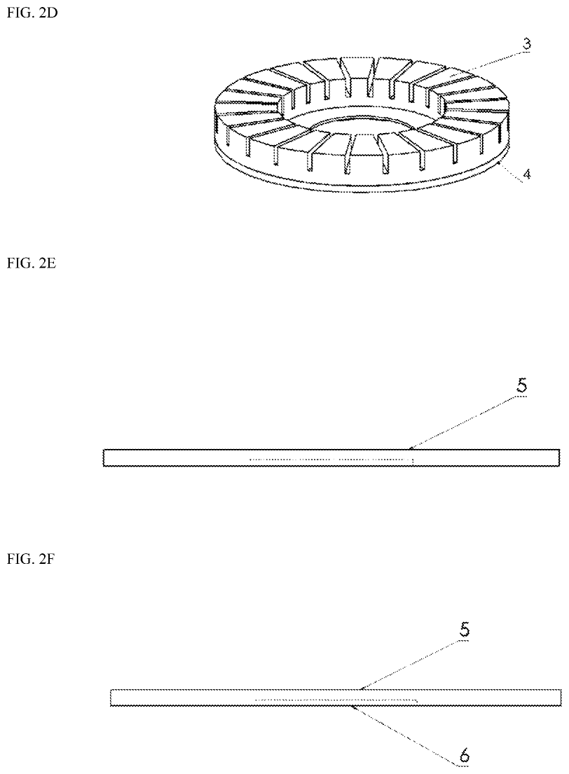

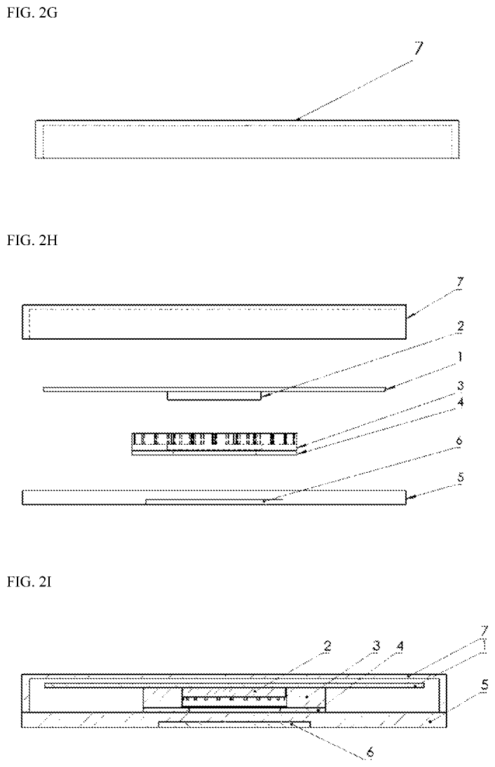

Referring to FIGS. 2A through 2I, an implementation method of an attractive force type micro-rotating mechanism in the embodiment, comprising the following basic processing steps: step one, referring to FIG. 2A, machining the wafer 1 with the diameter phi of 25 mm on a glass sheet with the thickness of 0.3 mm by using a milling machine; step two, referring to FIG. 2B, bonding the wafer 1 and the rubidium-iron-boron first magnet 2 with the diameter phi of 6.8 mm and the thickness of 0.6 mm by using a piezoelectric displacement table to obtain the rotor part of the ultrasonic motor; step three, referring to FIG. 2C, milling the phosphor bronze sheet with the thickness of 2 mm into 1.4 mm, milling 24 radical grooves with the depths of 0.8 mm by using a 0.2 mm micro-milling cutter, and milling a hole with the inner diameter phi of 6.9 mm and the depth of 1.2 mm, a through hole with the diameter phi of 4.5 mm and an excircle with the diameter phi of 12 mm by using a 1 mm milling cutter to obtain the phosphor bronze elastic body 3; step four, referring to FIG. 2D, bonding the phosphor bronze elastic body 3 and the piezoelectric ceramic 4 by using the piezoelectric displacement table to obtain the stator part of the ultrasonic motor; step five, referring to FIG. 2E, milling a hole with the diameter phi of 10 mm and the depth of 0.4 mm on a PMMA sheet with the thickness of 1 mm, cutting an excircle with the diameter phi of 28 mm on the sheet for cutting the excircle so as to obtain the first base; step six, referring to FIG. 2F, embedding the rubidium-iron-boron second magnet 6 with the diameter phi of 10 mm and the thickness of 0.4 mm into the hole with the diameter phi of 10 mm and the depth of 0.4 mm in the first base 5 so as to obtain the magnetic base; step seven, referring to FIG. 2G, milling a hole with the diameter phi of 27 mm and the depth of 2.2 mm on a PMMA sheet with the thickness of 2.5 mm, cutting an excircle with the diameter phi of 28 mm on the sheet for cutting the excircle so as to obtain the first shell 7; and step eight, referring to FIGS. 2H and 2I, assembling the shell, the rotor, the stator and the magnetic base together from top to bottom to obtain the complete motor.

The material of the glass wafer 1 may also be silicon, steel, copper, aluminum, plastic or the like, and the material of the phosphor bronze elastic body 3 may also be stainless steel, aluminum or the like.

### Embodiment 2

The embodiment is a repulsive force type rotating mechanism, which consists of the wafer 1 made of a glass material with the diameter phi of 25 mm and the thickness of 0.3 mm, the rubidium-iron-boron first magnet 2 with the diameter phi of 6.8 mm and the thickness of 0.6 mm, the toothed annular phosphor bronze elastic body 3 with the inner diameter phi of 6.9 mm and the outer diameter phi of 12 mm, the piezoelectric ceramic 4 with electrodes with the thickness of 0.3 mm, the inner diameter phi of 6.9 mm and the outer diameter phi of 12 mm, the rubidium-iron-boron second magnet 6 with the diameter phi of 6.8 mm and the thickness of 0.6 mm, the second base 8 with the diameter phi of 28 mm and the thickness of 1 mm, and the second shell 9 made of a PMMA material. The glass wafer 1 is plated with fan-shaped filter films, with six channels, capable of transmitting visible light of six different wave bands. Each sector is 60 degrees, each sector-shaped filter film is composed of four layers of thin films, each sector-shaped filter film comprises a chromium film of 1 nm, a silver film of 18 nm, a silicon film of 20-40 nm and a silver film of 18 nm from bottom to top respectively, and the wavelength of transmitted visible light is realized by changing the thickness of the silicon film. The wafer 1 and the first magnet 2 form the rotor part, and the wafer 1 and the first magnet 2 are bonded coaxially. A layer of wear-resistant material, such as polytetrafluoroethylene-based friction material, may be added to the wafer 1 to improve mechanical properties and prolong service life. The elastic body 3 and the piezoelectric ceramic 4 form the stator part, and the elastic body 3 and the piezoelectric ceramic 4 are also bonded coaxially. The elastic body 3 is of an annular structure, and mechanical vibration of the piezoelectric ceramic 4 is about to propagate in the elastic body 3 in the form of waves. The reinforcing rib on the inner ring of the elastic body 3 is used for increasing the strength and rigidity of the elastic body 3 and overcoming twisted deformation caused by uneven stress during working. On one hand, the tooth-shaped structure on the elastic body 3 is used for amplifying the vibration amplitude of the stator under the condition that the bending rigidity of the stator ring is basically kept unchanged, and on the other hand, debris generated by friction between the stator and the rotor can be accommodated in grooves of the tooth-shaped structure, so that the normal operation of the motor is guaranteed. The stator, the rotor and the second magnet 6 are coaxially assembled, the first magnet 2 on the rotor and the stator are in clearance fit to ensure normal rotation. The repulsive force type rotating mechanism utilizes mutual repulsion of the first magnet 2 on the rotor and the second magnet 6 on the second shell 9 with same magnetic poles to provide pre-pressure required for rotation.

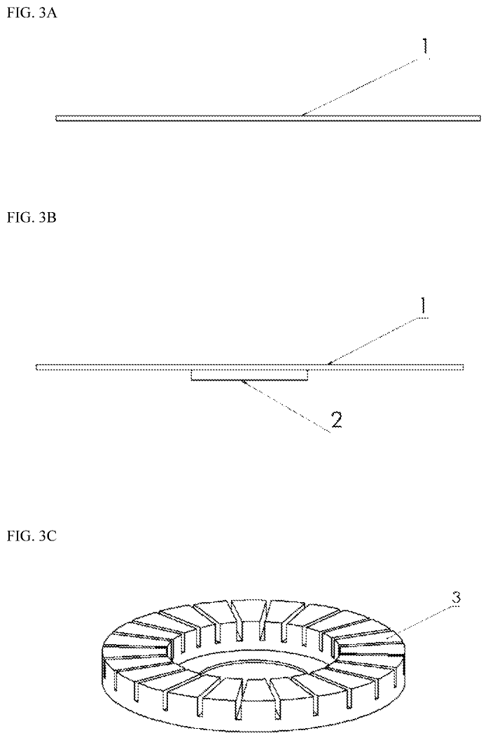

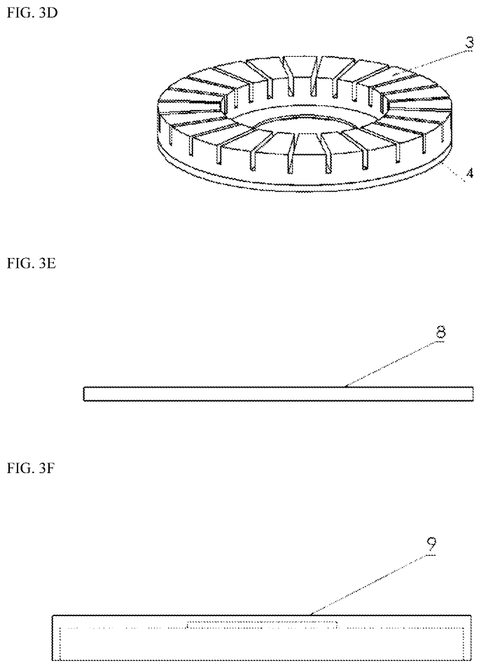

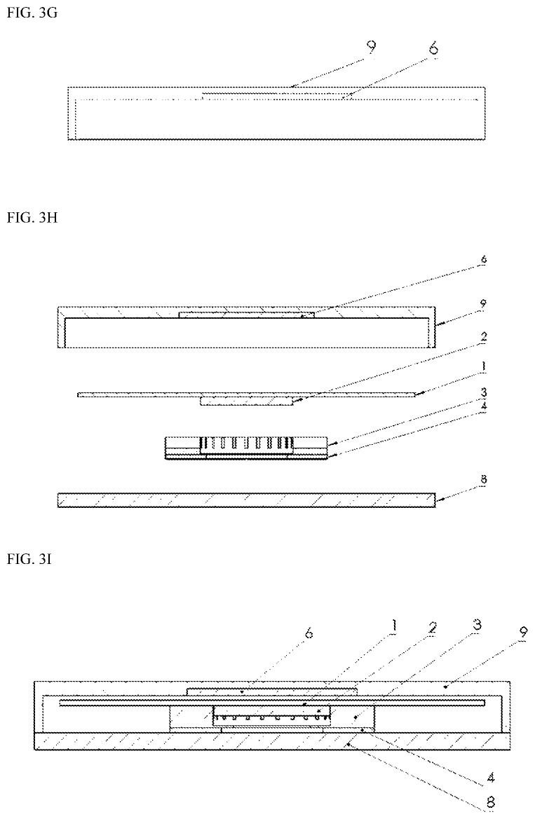

Referring to FIGS. 3A through 3I, an implementation method of a repulsive force type micro-rotating mechanism in the embodiment, comprising the following basic processing steps:

step one, referring to FIG. 3A, machining the glass wafer 1 with the diameter phi of 25 mm on a glass sheet with the thickness of 0.3 mm by using a milling machine, evaporating six filtering channels on an electron beam evaporation film plating machine on the wafer, each channel is sector-shaped by 60 degrees, the whole glass sheet is covered with the channels, each sector-shaped channel is composed of four films which are a chromium film of 1 nm, a silver film of 18 nm, a silicon film of 20-40 nm and a silver film of 18 nm from bottom to top respectively, only the middle silicon films of the channels are different in thicknesses, which are 20 nm, 24 nm, 28 nm, 32 nm, 36 nm and 40 nm respectively.

Step two, referring to FIG. 3B, bonding the wafer 1 and the rubidium-iron-boron first magnet 2 with the diameter phi of 6.8 mm and the thickness of 0.6 mm by using a piezoelectric displacement table to obtain the rotor part of the ultrasonic motor; step three, referring to FIG. 3C, milling a phosphor bronze sheet with the thickness of 2 mm into 1.4 mm, milling 24 radical grooves with the depths of 0.8 mm by using a 0.2 mm micro-milling cutter, and milling a hole with the inner diameter phi of 6.9 mm and the depth of 1.2 mm, a through hole with the diameter phi of 4.5 mm and an excircle with the diameter phi of 12 mm by using a 1 mm milling cutter to obtain the phosphor bronze elastic body 3; step four, referring to FIG. 3D, bonding the phosphor bronze elastic body 3 and the piezoelectric ceramic 4 by using the piezoelectric displacement table to obtain the stator part of the ultrasonic motor; step five, referring to FIG. 3E, slicing a wafer with the diameter phi of 28 mm on a PMMA sheet with the thickness of 1 mm so as to obtain the second base 8; step six, referring to FIG. 3F, milling a hole with the diameter phi of 27 mm and the depth of 2.2 mm on the PMMA sheet with the thickness of 3 mm, cutting an excircle with the diameter phi of 28 mm on the sheet for cutting the excircle so as to obtain the second shell 9; step seven, referring to FIG. 3G, embedding the rubidium-iron-boron second magnet 6 with the diameter phi of 10 mm and the thickness of 0.4 mm into a hole with the diameter phi of 10 mm and the depth of 0.4 mm in the second base 8 so as to obtain the magnetic base; and step eight, referring to FIGS. 3H and 3I, assembling the magnetic shell, the rotor, the stator and the base together from top to bottom to obtain the complete motor.

The material of the glass wafer 1 may also be silicon, steel, copper, aluminum, plastic or the like, and the material of the phosphor bronze elastic body 3 may also be stainless steel, aluminum or the like.

What is claimed is:

1. A non-contact force type micro-rotating mechanism belonging to an attractive force type rotating mechanism, the mechanism comprising:
a wafer;
a first magnet;
an elastic body;
a piezoelectric ceramic
a first base;
a second magnet; and
a first shell,
wherein the wafer and the first magnet form a rotor part, and the wafer and the first magnet are bonded coaxially;
the elastic body and the piezoelectric ceramic form a stator part, and the elastic body and the piezoelectric ceramic are also bonded coaxially;
the elastic body is of an annular structure, and mechanical vibration of the piezoelectric ceramic is about to propagate in the elastic body in the form of waves; and
the stator part, the rotor part and the second magnet are coaxially assembled, the first magnet of the rotor part is arranged in the elastic body of the stator part, and the first magnet and the elastic body are in clearance fit to ensure normal rotation; the mechanism utilizes mutual attraction of the first magnet on the rotor part and the second magnet on the first base with opposite magnetic poles to provide pre-pressure required for rotation.

2. A non-contact force type micro-rotating mechanism belonging to a repulsive force type rotating mechanism, the mechanism comprising:
a wafer;
a first magnet;
an elastic body;
a piezoelectric ceramic;
a second magnet;
a second base; and
a first shell,
wherein the wafer and the first magnet form a rotor part, and the wafer and the first magnet are bonded coaxially;
the elastic body and the piezoelectric ceramic form a stator part, and the elastic body and the piezoelectric ceramic are also bonded coaxially;
the elastic body is of an annular structure, and mechanical vibration of the piezoelectric ceramic is about to propagate in the elastic body in the form of waves;
the stator part, the rotor part and the second magnet are coaxially assembled, the first magnet on the rotor part and the stator part are in clearance fit to ensure normal rotation; and
the mechanism utilizes mutual repulsion of the first magnet on the rotor part and the second magnet on a second shell with same magnetic poles to provide pre-pressure required for rotation.

3. The non-contact force type micro-rotating mechanism according to claim 1, wherein the elastic body is provided with a tooth-shaped structure, and radial grooves are formed between adjacent teeth.

4. The non-contact force type micro-rotating mechanism according to claim 2, wherein the elastic body is provided with a tooth-shaped structure, and radial grooves are formed between adjacent teeth.

5. The non-contact force type micro-rotating mechanism according to claim 1, wherein an inner ring of the elastic body is provided with a reinforcing rib.

6. The non-contact force type micro-rotating mechanism according to claim 2, wherein an inner ring of the elastic body is provided with a reinforcing rib.

7. The non-contact force type micro-rotating mechanism according to claim 1, wherein the wafer is provided with a layer of wear-resistant material.

8. The non-contact force type micro-rotating mechanism according to claim 2, wherein the wafer is provided with a layer of wear-resistant material.

9. A method of preparing a non-contact force type micro-rotating mechanism, comprising:
machining a wafer by using a machine tool;
bonding the wafer and a magnet by using a displacement table to obtain a rotor part of a motor;
machining a tooth-shaped elastic body by using the machine tool;
bonding the tooth-shaped elastic body and a piezoelectric ceramic by using the displacement table to obtain a stator part of the motor;
milling the first base on a substrate;
embedding a second magnet into the first base to obtain a magnetic base;
step seven, milling a first shell on another substrate; and
assembling the first shell, the rotor part, the stator part and the magnetic base together from top to bottom to obtain the complete motor.
